(19) United States
(12) Patent Application Publication
(10) Pub. No.: US 2026/0113960 A1
(43) Pub. Date: Apr. 23, 2026

(54) SEMICONDUCTOR DEVICE

(71) Applicant: Murata Manufacturing Co., Ltd., Nagaokakyo-shi (JP)

(72) Inventors: Takeshi Kagawa, Nagaokakyo-shi (JP); Korekiyo Ito, Nagaokakyo-shi (JP); Masatomi Harada, Nagaokakyo-shi (JP)

(21) Appl. No.: 19/401,766

(22) Filed: Nov. 26, 2025

Related U.S. Application Data
(63) Continuation of application No. PCT/JP2024/017951, filed on May 15, 2024.

(30) Foreign Application Priority Data
Jun. 7, 2023 (JP) 2023-094200

(51) Int. Cl. H10D 1/68; H10D 1/00

(52) U.S. Cl. CPC H10D 1/692; H10D 1/041

(57) ABSTRACT

A semiconductor device that includes a substrate having an insulating surface; a first electrode on the insulating surface; a dielectric film on the first electrode; and a second electrode on the dielectric film. The second electrode has a protruding shape in a sectional view.

### CROSS REFERENCE TO RELATED APPLICATIONS

The present application is a continuation of International application No. PCT/JP2024/017951, filed May 15, 2024, which claims priority to Japanese Patent Application No. 2023-094200, filed Jun. 7, 2023, the entire contents of each of which are incorporated herein by reference.

### TECHNICAL FIELD

The present disclosure relates to a semiconductor device.

### BACKGROUND ART

Patent Document 1 describes a technique in which an insulating film, a lower electrode, a dielectric film, an upper electrode, a protective film, and terminal electrodes are sequentially formed over a substrate to form a capacitor having a metal-insulator-metal (MIM) structure.

Patent Document 1: International Publication No. WO 2018/003445 SUMMARY OF THE DISCLOSURE

In such a capacitor having such a structure, equivalent series resistance (ESR) becomes lower when the electrode film thickness of the upper electrode is thicker. However, when the upper electrode is thick, variation in processing becomes large, and the area of the upper electrode varies. Thus, capacitance variation becomes large. Accordingly, the ESR and the capacitance variation are in a trade-off relationship. A semiconductor device that can function as a capacitor also has a similar problem.

The present disclosure has been made in order to solve the above problem, and an object thereof is to provide a semiconductor device capable of reducing both ESR and capacitance variation.

A semiconductor device of the present disclosure includes a substrate having an insulating surface; a first electrode on the insulating surface; a dielectric film on the first electrode, and a second electrode on the dielectric film. The second electrode has a protruding shape in a sectional view.

According to the present disclosure, it is possible to provide a semiconductor device capable of reducing both ESR and capacitance variation.

### BRIEF DESCRIPTION OF THE DRAWINGS

FIG. 1 is a plan view schematically depicting an example of a capacitor according to embodiment 1 of the present disclosure.

FIG. 2 is an example of a sectional view taken along line A-A of the capacitor depicted in FIG. 1.

FIG. 3A is a sectional view schematically depicting an example of a step of forming an insulating layer in embodiment 1.

FIG. 3B is a sectional view schematically depicting an example of a step of forming a lower electrode in embodiment 1.

FIG. 3C is a sectional view schematically depicting an example of a step of forming a dielectric film in embodiment 1.

FIG. 3D is a sectional view schematically depicting an example of a step of forming a metal film for an upper electrode in embodiment 1.

FIG. 3E is a sectional view schematically depicting an example of a first step of processing the metal film for the upper electrode in embodiment 1.

FIG. 3F is a sectional view schematically depicting an example of a second step of processing the metal film for the upper electrode in embodiment 1.

FIG. 3G is a sectional view schematically depicting an example of a step of forming a via in the dielectric film in embodiment 1.

FIG. 3H is a sectional view schematically depicting an example of a step of forming a protective layer in embodiment 1.

FIG. 3I is a sectional view schematically depicting an example of a step of forming outer electrodes in embodiment 1.

FIG. 4 is a sectional view schematically depicting an example of a capacitor according to embodiment 2 of the present disclosure.

FIG. 5A is a sectional view schematically depicting an example of a step of forming the insulating layer in embodiment 2.

FIG. 5B is a sectional view schematically depicting an example of a step of forming the lower electrode in embodiment 2.

FIG. 5C is a sectional view schematically depicting an example of a step of forming the dielectric film in embodiment 2.

FIG. 5D is a sectional view schematically depicting an example of a step of forming a lower layer of the upper electrode in embodiment 2.

FIG. 5E is a sectional view schematically depicting an example of a step of forming an upper layer of the upper electrode in embodiment 2.

FIG. 5F is a sectional view schematically depicting an example of a step of forming the via in the dielectric film in embodiment 2.

FIG. 5G is a sectional view schematically depicting an example of a step of forming the protective layer in embodiment 2.

FIG. 5H is a sectional view schematically depicting an example of a step of forming the outer electrodes in embodiment 2.

FIG. 6 is a sectional view schematically depicting an example of a capacitor according to embodiment 3 of the present disclosure.

FIG. 7A is a sectional view schematically depicting an example of a step of forming the insulating layer in embodiment 3.

FIG. 7B is a sectional view schematically depicting an example of a step of forming the lower electrode in embodiment 3.

FIG. 7C is a sectional view schematically depicting an example of a step of forming the dielectric film in embodiment 3.

FIG. 7D is a sectional view schematically depicting an example of a step of forming the lower layer of the upper electrode in embodiment 3.

FIG. 7E is a sectional view schematically depicting an example of a step of forming the upper layer of the upper electrode in embodiment 3.

FIG. 7F is a sectional view schematically depicting an example of a step of forming the via in the dielectric film in embodiment 3.

FIG. 7G is a sectional view schematically depicting an example of a step of forming the protective layer in embodiment 3.

FIG. 7H is a sectional view schematically depicting an example of a step of forming the outer electrodes in embodiment 3.

FIG. 8 is a sectional view schematically depicting an example of a capacitor according to embodiment 4 of the present disclosure.

FIG. 9A is a sectional view schematically depicting an example of a step of forming the insulating layer in embodiment 4.

FIG. 9B is a sectional view schematically depicting an example of a step of forming the lower electrode in embodiment 4.

FIG. 9C is a sectional view schematically depicting an example of a step of forming the dielectric film in embodiment 4.

FIG. 9D is a sectional view schematically depicting an example of a step of forming metal films for the upper electrode in embodiment 4.

FIG. 9E is a sectional view schematically depicting an example of a first step of processing the metal film for the upper electrode in embodiment 4.

FIG. 9F is a sectional view schematically depicting an example of a second step of processing the metal film for the upper electrode in embodiment 4.

FIG. 9G is a sectional view schematically depicting an example of a third step of processing the metal film for the upper electrode in embodiment 4.

FIG. 9H is a sectional view schematically depicting an example of a step of forming the via in the dielectric film in embodiment 4.

FIG. 9I is a sectional view schematically depicting an example of a step of forming the protective layer in embodiment 4.

FIG. 9J is a sectional view schematically depicting an example of a step of forming the outer electrodes in embodiment 4.

FIG. 10 is a sectional view schematically depicting an example of a capacitor according to embodiment 5 of the present disclosure.

### DESCRIPTION OF THE PREFERRED EMBODIMENTS

A semiconductor device of the present disclosure is described below.

However, the present disclosure is not limited to the following configurations, and modifications can be made and applied as appropriate without departing from the gist of the present disclosure. A combination of two or more of the individual preferable configurations described below also constitutes the present disclosure.

Each embodiment described below is given as an example, and it is obvious that partial replacement or combination of configurations shown in different embodiments is possible. In embodiment 2 and subsequent embodiments, description of matters common to embodiment 1 is omitted, and mainly differences are described. In particular, similar operation and effects resulting from a similar configuration are not described repeatedly for each embodiment.

In the following description, when the respective embodiments are not particularly distinguished, a term “semiconductor device of the present disclosure” is simply used. The shapes, arrangements, and the like of the semiconductor device of the present disclosure and the respective components thereof are not limited to depicted examples.

Further, in the following, a description is given by taking a capacitor as an example as an embodiment of the semiconductor device of the present disclosure. The semiconductor device of the present disclosure may be a capacitor itself, or may be a device including a capacitor.

### Embodiment 1

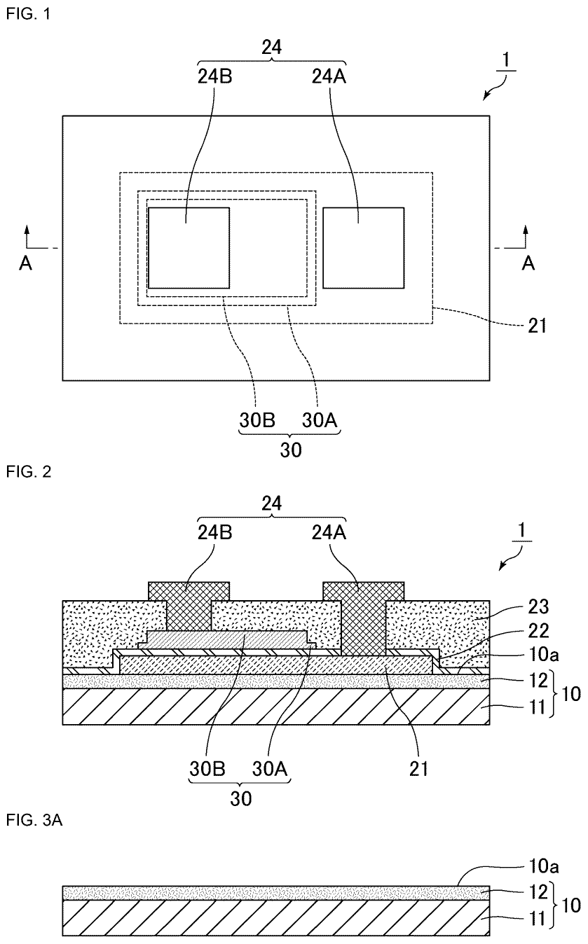

A capacitor according to embodiment 1 of the present disclosure is described. FIG. 1 is a plan view schematically depicting an example of the capacitor according to embodiment 1 of the present disclosure. FIG. 2 is an example of a sectional view taken along line A-A of the capacitor depicted in FIG. 1.

A capacitor 1 depicted in FIGS. 1 and 2 includes a substrate 10 having an insulating surface (main surface) 10a, a lower electrode 21 disposed on the insulating surface 10a, a dielectric film 22 disposed on the lower electrode 21, and an upper electrode 30 disposed on the dielectric film 22.

Here, the substrate 10 has a semiconductor substrate 11 and an insulating layer 12 disposed on the semiconductor substrate 11. However, the insulating layer 12 can be omitted when the substrate 10 is an insulating substrate of glass, alumina, or the like.

The capacitor 1 further includes a protective layer 23 disposed on the dielectric film 22 and the upper electrode 30, and outer electrodes 24 penetrating the protective layer 23. The outer electrodes 24 include a first outer electrode 24A connected to the lower electrode 21 and a second outer electrode 24B connected to the upper electrode 30. The first outer electrode 24A penetrates the protective layer 23 and the dielectric film 22, and the second outer electrode 24B penetrates the protective layer 23.

The capacitor 1 may further include a moisture-resistant film (not depicted) disposed on the dielectric film 22 and the upper electrode 30.

In the capacitor 1, the lower electrode 21, the dielectric film 22, and the upper electrode 30 are stacked in that order to form a MIM capacitor structure. By applying a voltage between the lower electrode 21 and the upper electrode 30, a charge can be accumulated in the dielectric film 22.

Further, as depicted in FIG. 2, the upper electrode 30 has a protruding shape in a sectional view. Thus, a capacitor having small capacitance variation and low ESR can be realized. Specifically, the capacitance variation becomes small because the capacitance is defined by processing a thin film serving as a lower portion 30A of the upper electrode 30. In addition, the ESR can be reduced because an upper portion 30B of the upper electrode 30 is present and the upper electrode 30 can be made thicker.

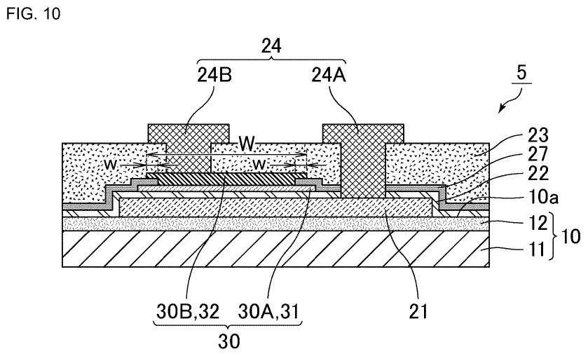

In the present specification, the term “protruding shape” means a shape that has a lower portion and an upper portion disposed on the lower portion and in which the entire upper portion exists inside the lower portion in plan view. Accordingly, the end surface of the upper portion is not particularly limited to a flat surface such as a vertical surface (see FIG. 2), and may be an uneven surface. For example, an end portion of the upper portion may have an overhanging shape (see FIG. 10 described later).

Further, in the present specification, the side closer to the substrate is defined as the “lower” side, and the side farther from the substrate is defined as the “upper” side.

As depicted in FIG. 1, the substrate 10, the lower electrode 21, and the upper electrode 30 are all rectangular in plan view. Further, the lower electrode 21 is formed within a region of the substrate 10 in plan view, and the upper electrode 30 is formed within a formation region of the lower electrode 21 in plan view.

Further, as depicted in FIG. 1, both the lower portion 30A (proximal to the substrate) and the upper portion 30B (distal from the substrate) of the upper electrode 30 are rectangular. In addition, the upper portion 30B is formed within a formation region of the lower portion 30A in plan view. That is, in plan view, the lower portion 30A protrudes outward in a frame shape from the upper portion 30B over the entire periphery of the upper portion 30B. In this manner, the lower portion 30A is composed of a fringe portion (flange portion) protruding outward over the entire periphery from the upper portion 30B, and a central portion located at the same height as the fringe portion, and the upper portion 30B corresponds to a part of the upper electrode 30 excluding the lower portion 30A.

The dimensions (size in an in-plane direction) of each of the lower portion 30A and the upper portion 30B of the upper electrode 30 are not particularly limited. For example, the dimensions of the lower portion 30A can be set depending on a desired capacitance value of the capacitor 1. Further, the length of each side of the upper portion 30B may be, for example, 50% to 99% of the length of a corresponding side (adjacent side) of the lower portion 30A, and is preferably 90% to 99% of the length of the corresponding side (adjacent side) of the lower portion 30A.

In the present embodiment, as depicted in FIG. 2, the upper electrode 30 is composed of a single layer. That is, the upper portion 30B of the upper electrode 30 and the lower portion 30A of the upper electrode 30 are composed of the same material, and no boundary exists between them. Thus, it is possible to prevent the capacitor 1 from suffering from any adverse effect attributed to such a boundary.

It is preferable that the thickness of the lower portion 30A of the upper electrode 30 be smaller than that of the upper portion 30B of the upper electrode 30. This can effectively reduce the ESR and the capacitance variation.

It is preferable that the thickness of the lower portion 30A be less than 1 μm. This can further reduce the capacitance variation. The thickness of the lower portion 30A is more preferably 0.05 μm to 0.5 μm, and further preferably 0.05 μm to 0.1 μm. The thickness of the lower portion 30A may be the thickness of the fringe portion of the lower portion 30A.

It is preferable that the thickness of the upper portion 30B be 1 μm or more. This can further reduce the ESR. The thickness of the upper portion 30B is more preferably 1 μm to 5 μm, and further preferably 3 μm to 5 μm. The thickness of the upper portion 30B may be the thickness of a part located on the upper side relative to the fringe portion of the lower portion 30A.

Subsequently, a manufacturing method for the capacitor according to the present embodiment is described.

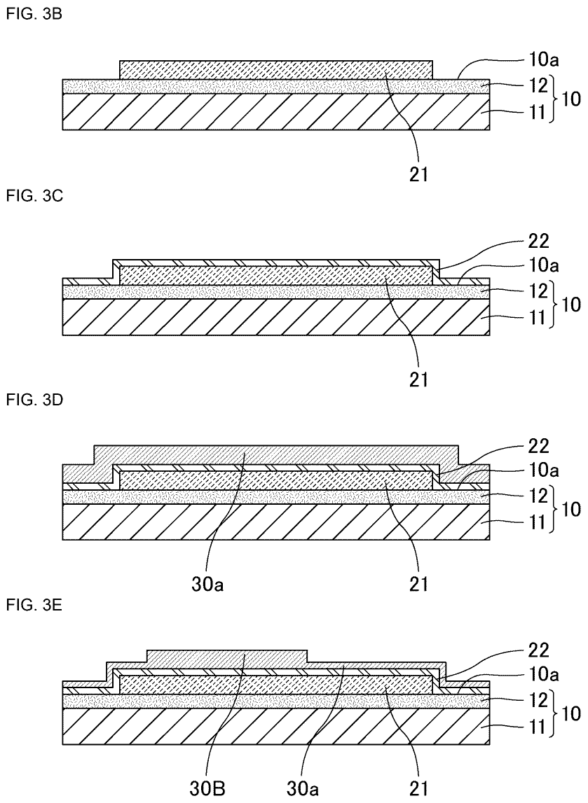

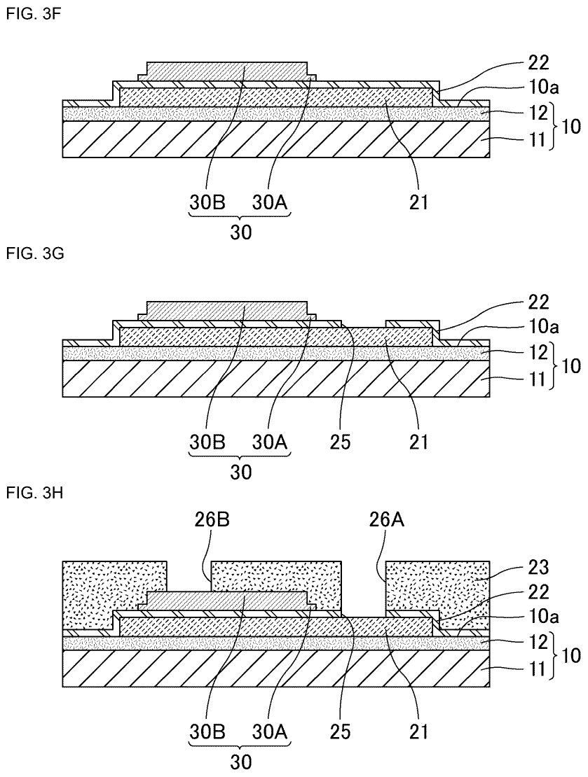

FIG. 3A is a sectional view schematically depicting an example of a step of forming the insulating layer in embodiment 1. FIG. 3B is a sectional view schematically depicting an example of a step of forming the lower electrode in embodiment 1. FIG. 3C is a sectional view schematically depicting an example of a step of forming the dielectric film in embodiment 1. FIG. 3D is a sectional view schematically depicting an example of a step of forming a metal film for the upper electrode in embodiment 1. FIG. 3E is a sectional view schematically depicting an example of a first step of processing the metal film for the upper electrode in embodiment 1. FIG. 3F is a sectional view schematically depicting an example of a second step of processing the metal film for the upper electrode in embodiment 1. FIG. 3G is a sectional view schematically depicting an example of a step of forming a via in the dielectric film in embodiment 1. FIG. 3H is a sectional view schematically depicting an example of a step of forming the protective layer in embodiment 1. FIG. 3I is a sectional view schematically depicting an example of a step of forming the outer electrodes in embodiment 1.

Although attention is focused on one capacitor in FIGS. 3A to 3I, a plurality of capacitors may be simultaneously formed on the substrate. That is, a collective board having the capacitors may be manufactured, and thereafter be diced into individual capacitors. The same applies to embodiment 2 and subsequent embodiments.

First, as depicted in FIG. 3A, the insulating layer 12 of SiO₂, SiN, Al₂O₃, or the like is formed on the semiconductor substrate 11 such as a silicon substrate or a gallium arsenide substrate by chemical vapor deposition (CVD), physical vapor deposition (PVD), or the like. By this step, the substrate 10 having the insulating surface 10a is prepared. The insulating layer 12 can be omitted when the substrate 10 is an insulating substrate of glass, alumina, or the like.

Next, as depicted in FIG. 3B, the lower electrode 21 is formed on the insulating surface 10a (insulating layer 12) by lift-off, plating, etching, or the like. As a material of the lower electrode 21, Cu, Ag, Au, Al, Pt, or an alloy containing at least one of these metals is preferable.

Next, as depicted in FIG. 3C, the dielectric film 22 is deposited over the entire surface of the substrate 10 by CVD, PVD, or the like. As a material of the dielectric film 22, an oxide or a nitride such as SiO₂, SiN, Al₂O₃, HfO₂, or Ta₂O₅ is preferable.

Next, as depicted in FIG. 3D, a metal film 30a to serve as the upper electrode 30 is formed on the dielectric film 22 by CVD, PVD, or the like. As a material of the upper electrode 30 (metal film 30a), Cu, Ag, Au, Al, Pt, or an alloy containing at least one of these metals is preferable.

Next, as depicted in FIG. 3E, a resist pattern for the upper portion 30B of the upper electrode 30 is formed by photolithography, and the metal film 30a is processed by etching. At this time, the etching time and the like are adjusted such that a thin film is left.

Next, as depicted in FIG. 3F, a resist pattern for the lower portion 30A of the upper electrode 30 is formed by photolithography, and the lower portion 30A is formed by etching. At this time, it is preferable to use a method such as dry etching, which enables high processing accuracy.

Next, as depicted in FIG. 3G, a via (opening) 25 for electrical connection to the lower electrode 21 is formed in the dielectric film 22 by etching or the like.

Next, as depicted in FIG. 3H, the protective layer 23 is formed. As a material of the protective layer 23, a resin material such as polyimide is preferable. In the protective layer 23, a via (opening) 26A over the via 25 and a via (opening) 26B over the upper electrode 30 are formed. The protective layer 23 can be formed by, for example, spin coating or the like. Further, a pattern of the protective layer 23 can be formed by photolithography, etching, and the like.

A moisture-resistant film of SiN or the like may be formed under the protective layer 23 by CVD, PVD, or the like.

Next, as depicted in FIG. 3I, the outer electrodes 24 are formed by lift-off, plating, etching, or the like. Specifically, the first outer electrode 24A is formed to fill the vias 25 and 26A, and the second outer electrode 24B is formed to fill the via 26B. As a material of the outer electrodes 24, Cu, Ni, Ag, Au, or Al is preferable, and Au is preferable for the outermost surface thereof. The outer electrodes 24 may have a single-layer structure or a multilayer structure.

In a case of manufacturing a collective board having a plurality of capacitors, the collective board is thinned to a desired element thickness by back grinding, and then is diced into individual pieces by blade dicing, stealth dicing, plasma dicing, or the like. That is, the collective board is cut into sizes of individual capacitors.

Through the above process, the capacitor 1 according to the present embodiment is manufactured.

### Embodiment 2

The present embodiment is different from embodiment 1 in that the upper electrode is formed of a plurality of layers, here, two layers.

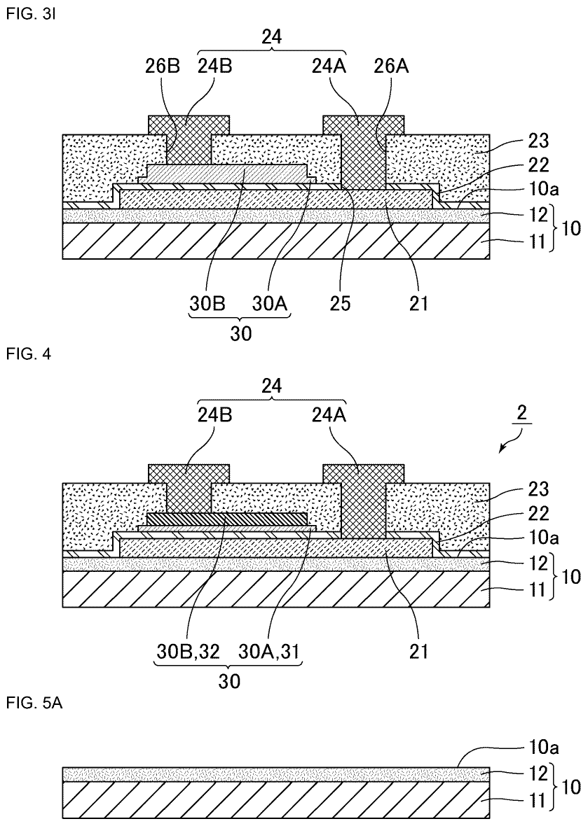

FIG. 4 is a sectional view schematically depicting an example of a capacitor according to embodiment 2 of the present disclosure. FIG. 4 corresponds to the sectional view taken along line A-A of the capacitor depicted in FIG. 1.

In a capacitor 2 depicted in FIG. 4, the upper electrode 30 has a lower layer 31 (proximal to the substrate) and an upper layer 32 disposed on the lower layer 31 (and distal from the substrate). This allows the protruding structure of the upper electrode 30 to be formed from different materials. Thus, when a material having high processability is combined with a material having low resistance, the ESR can be further reduced and the capacitance variation can be made smaller. In addition, as compared with embodiment 1, the film thickness of the lower portion 30A (lower layer 31) of the upper electrode 30 can be easily controlled.

Thus, in the present embodiment, the lower layer 31 corresponds to the lower portion 30A of the upper electrode 30, and the upper layer 32 corresponds to the upper portion 30B of the upper electrode 30.

Further, the upper layer 32 is disposed only on the upper surface (main surface) of the lower layer 31. That is, in plan view, the whole of the upper layer 32 exists inside the lower layer 31.

As described above, the upper layer 32 and the lower layer 31 may contain different materials from each other. That is, the material forming the upper layer 32 may be different from the material forming the lower layer 31. This makes it possible to use materials suitable for each of the upper layer 32 and the lower layer 31. In this case, it is preferable that the specific resistance of the material forming the upper layer 32 be lower than that of the material forming the lower layer 31. Further, it is preferable that the lower layer 31 be formed of a material having high processability and the upper layer 32 be formed of a material having low resistance.

On the other hand, the upper layer 32 and the lower layer 31 may contain the same material, and the material forming the upper layer 32 may be the same as the material forming the lower layer 31. This can prevent generation of a boundary between the upper layer 32 and the lower layer 31. Thus, it is possible to prevent the capacitor 2 from suffering from any adverse effect attributed to such a boundary.

In the present specification, the term “same” includes cases that are substantially the same.

Subsequently, a manufacturing method for the capacitor according to the present embodiment is described.

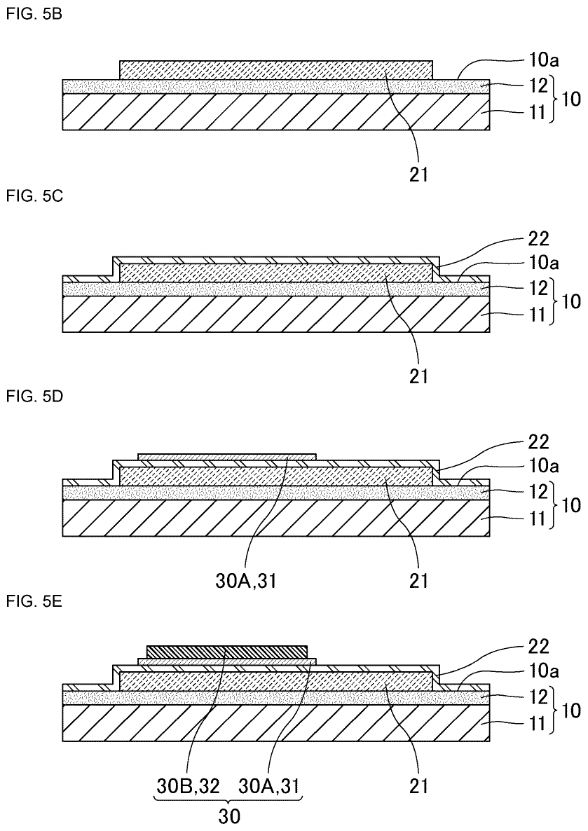

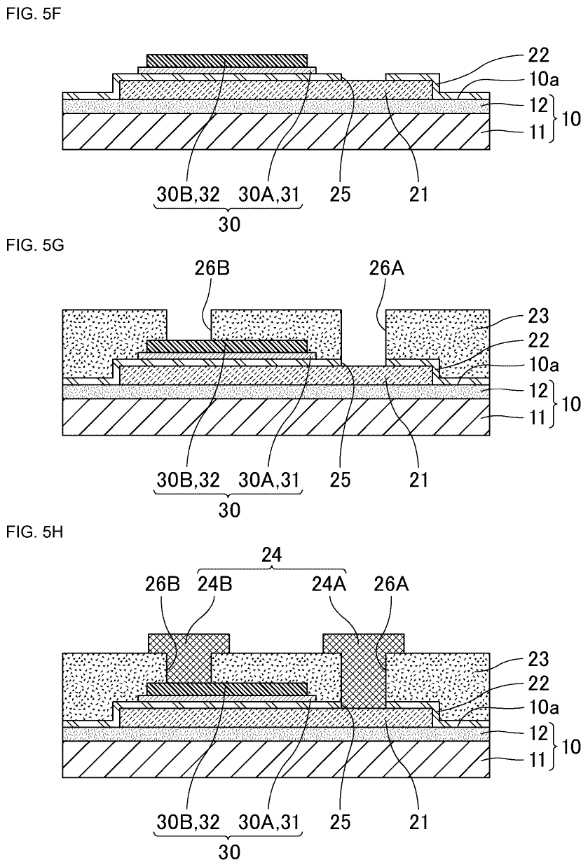

FIG. 5A is a sectional view schematically depicting an example of a step of forming the insulating layer in embodiment 2. FIG. 5B is a sectional view schematically depicting an example of a step of forming the lower electrode in embodiment 2. FIG. 5C is a sectional view schematically depicting an example of a step of forming the dielectric film in embodiment 2. FIG. 5D is a sectional view schematically depicting an example of a step of forming the lower layer of the upper electrode in embodiment 2. FIG. 5E is a sectional view schematically depicting an example of a step of forming the upper layer of the upper electrode in embodiment 2. FIG. 5F is a sectional view schematically depicting an example of a step of forming the via in the dielectric film in embodiment 2. FIG. 5G is a sectional view schematically depicting an example of a step of forming the protective layer in embodiment 2. FIG. 5H is a sectional view schematically depicting an example of a step of forming the outer electrodes in embodiment 2.

First, as depicted in FIGS. 5A to 5C, similarly to embodiment 1, the insulating layer 12, the lower electrode 21, and the dielectric film 22 are formed in that order over the semiconductor substrate 11.

Next, as depicted in FIG. 5D, the lower layer 31 of the upper electrode 30 is formed on the dielectric film 22. As a material of the lower layer 31, Cu, Ag, Au, Al, Pt, or an alloy containing at least one of these metals is preferable. At this time, it is preferable to use a method such as dry etching with high processing accuracy.

Next, as depicted in FIG. 5E, the upper layer 32 of the upper electrode 30 is selectively formed only on the upper surface of the lower layer 31 of the upper electrode 30 by a method independent of an underlying layer, such as lift-off or plating. Although lift-off and plating have lower processing accuracy than dry etching, this is not a particular problem because the upper layer 32 does not affect the capacitance. As a material of the upper layer 32, Cu, Ag, Au, Al, Pt, or an alloy containing at least one of these metals is preferable.

Thereafter, similarly to embodiment 1, as depicted in FIGS. 5F to 5H, the via 25, the protective layer 23, and the outer electrodes 24 are formed in that order. Then, the obtained structure is thinned to a desired element thickness, followed by dicing into individual pieces.

Through the above process, the capacitor 2 according to the present embodiment is manufactured.

### Embodiment 3

The present embodiment is different from embodiment 2 in that the lower layer of the upper electrode is formed to be thick and the upper layer that is thin is formed to cover the lower layer.

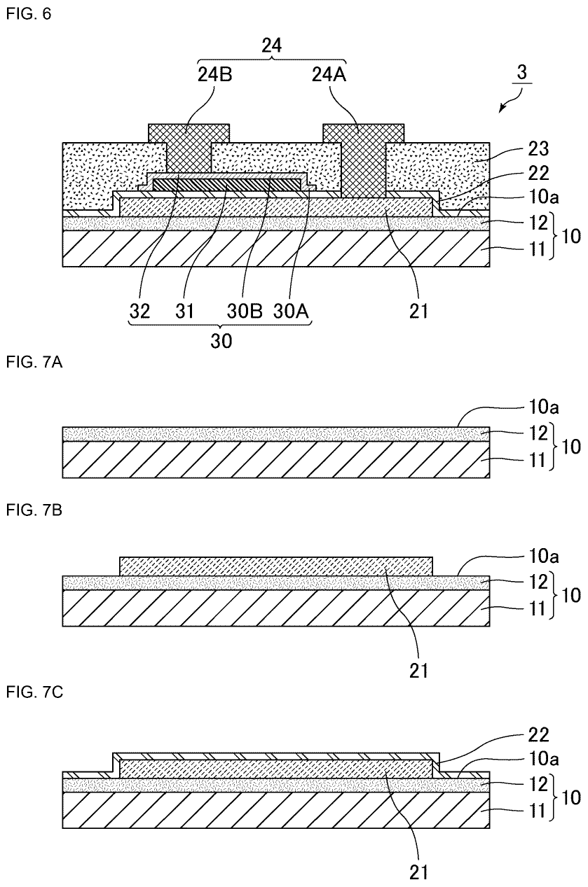

FIG. 6 is a sectional view schematically depicting an example of a capacitor according to embodiment 3 of the present disclosure. FIG. 6 corresponds to the sectional view taken along line A-A of the capacitor depicted in FIG. 1.

In a capacitor 3 depicted in FIG. 6, the upper layer 32 of the upper electrode 30 is disposed to cover the upper surface and the side surface of the lower layer 31 of the upper electrode 30. This provides an effect that a process technique for improving dimensional accuracy can be applied in addition to the effects of embodiment 2. Specifically, in embodiment 2, when the lower layer 31 and the upper layer 32 of the upper electrode 30 are formed of the same material, only a method such as lift-off or plating with low processing accuracy can be used for forming the upper layer 32. In contrast, in the present embodiment, a method such as dry etching with high processing accuracy can be used for forming the upper layer 32.

In the present embodiment, an end portion (fringe portion in contact with the dielectric film 22) of the upper layer 32 and a lower portion (portion located at the same height as the end portion of the upper layer 32) of the lower layer 31 correspond to the lower portion 30A of the upper electrode 30. In addition, an upper portion of the lower layer 31 (portion excluding the lower portion in the lower layer 31) and a portion excluding the end portion in the upper layer 32 correspond to the upper portion 30B of the upper electrode 30.

Further, the upper layer 32 is disposed to cover the entire upper surface and the entire side surface of the lower layer 31.

Similarly to embodiment 2, the material forming the upper layer 32 may be different from the material forming the lower layer 31. In the present embodiment, however, it is preferable that the specific resistance of the material forming the lower layer 31 be lower than that of the material forming the upper layer 32. Further, it is preferable that the upper layer 32 be formed of a material having high processability and the lower layer 31 be formed of a material having low resistance.

Further, similarly to embodiment 2, the upper layer 32 and the lower layer 31 may contain the same material, and the material forming the upper layer 32 may be the same as the material forming the lower layer 31.

Subsequently, a manufacturing method for the capacitor according to the present embodiment is described.

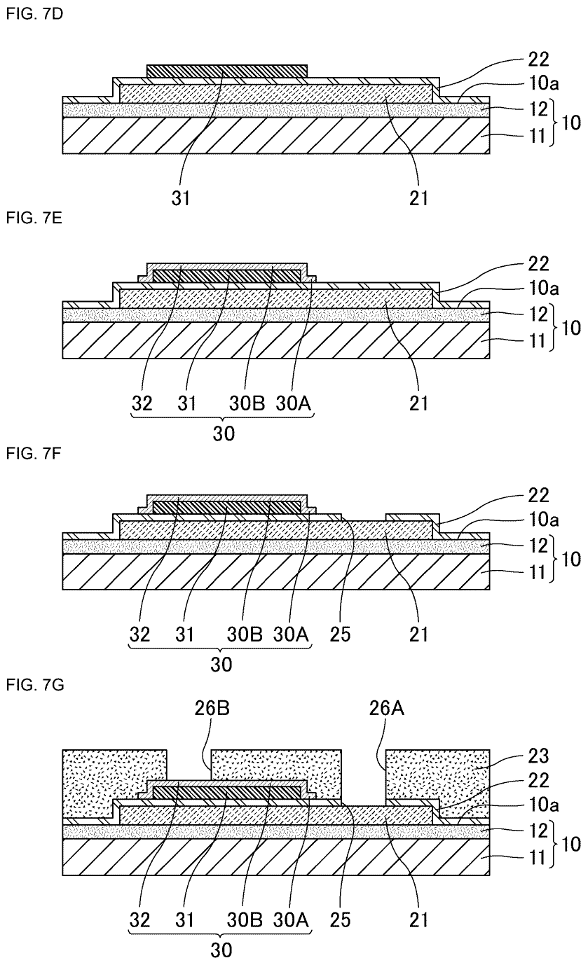

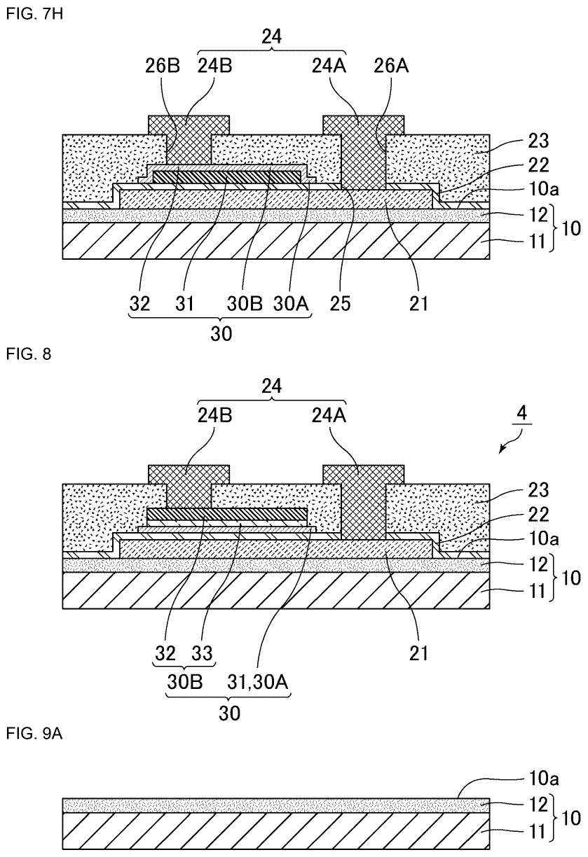

FIG. 7A is a sectional view schematically depicting an example of a step of forming the insulating layer in embodiment 3. FIG. 7B is a sectional view schematically depicting an example of a step of forming the lower electrode in embodiment 3. FIG. 7C is a sectional view schematically depicting an example of a step of forming the dielectric film in embodiment 3. FIG. 7D is a sectional view schematically depicting an example of a step of forming the lower layer of the upper electrode in embodiment 3. FIG. 7E is a sectional view schematically depicting an example of a step of forming the upper layer of the upper electrode in embodiment 3. FIG. 7F is a sectional view schematically depicting an example of a step of forming the via in the dielectric film in embodiment 3. FIG. 7G is a sectional view schematically depicting an example of a step of forming the protective layer in embodiment 3. FIG. 7H is a sectional view schematically depicting an example of a step of forming the outer electrodes in embodiment 3.

First, as depicted in FIGS. 7A to 7C, similarly to embodiment 1, the insulating layer 12, the lower electrode 21, and the dielectric film 22 are formed in that order over the semiconductor substrate 11.

Next, as depicted in FIG. 7D, the lower layer 31 of the upper electrode 30 is formed on the dielectric film 22. As a material of the lower layer 31, Cu, Ag, Au, Al, Pt, or an alloy containing at least one of these metals is preferable. The method for forming the lower layer 31 is not particularly limited, and may be a method such as lift-off or plating with low processing accuracy or a method such as dry etching with high processing accuracy. That is, in the present embodiment, there are more options for the process of forming the lower layer 31 as compared with embodiment 2.

Next, as depicted in FIG. 7E, the upper layer 32 of the upper electrode 30 is formed to cover the upper surface and the side surface of the lower layer 31 of the upper electrode 30. As a material of the upper layer 32, Cu, Ag, Au, Al, Pt, or an alloy containing at least one of these metals is preferable. At this time, it is preferable to use a method such as dry etching with high processing accuracy.

Thereafter, similarly to embodiment 1, as depicted in FIGS. 7F to 7H, the via 25, the protective layer 23, and the outer electrodes 24 are formed in that order. Then, the obtained structure is thinned to a desired element thickness, followed by dicing into individual pieces.

Through the above process, the capacitor 3 according to the present embodiment is manufactured.

### Embodiment 4

The present embodiment is different from embodiment 2 in that another metal layer is inserted between a first layer (lower layer) and a second layer (upper layer) of the upper electrode.

FIG. 8 is a sectional view schematically depicting an example of a capacitor according to embodiment 4 of the present disclosure. FIG. 8 corresponds to the sectional view taken along line A-A of the capacitor depicted in FIG. 1.

In a capacitor 4 depicted in FIG. 8, the upper electrode 30 has a metal layer 33 disposed between the upper layer 32 and the lower layer 31. This provides effects similar to those of embodiment 3. This is because the metal layer 33 between the upper layer 32 and the lower layer 31 functions as a stopper film during etching.

In the present embodiment, the lower layer 31 corresponds to the lower portion 30A of the upper electrode 30, and the upper layer 32 and the metal layer 33 correspond to the upper portion 30B of the upper electrode 30.

Further, the upper layer 32 and the metal layer 33 are disposed only over the upper surface of the lower layer 31. That is, in plan view, the whole of the upper layer 32 and the whole of the metal layer 33 exist inside the lower layer 31. In addition, the upper layer 32 is disposed over the entire upper surface of the metal layer 33. That is, in plan view, a formation region of the upper layer 32 coincides with a formation region of the metal layer 33. Here, the term “coincide with” includes cases in which they substantially coincide with each other.

Subsequently, a manufacturing method for the capacitor according to the present embodiment is described.

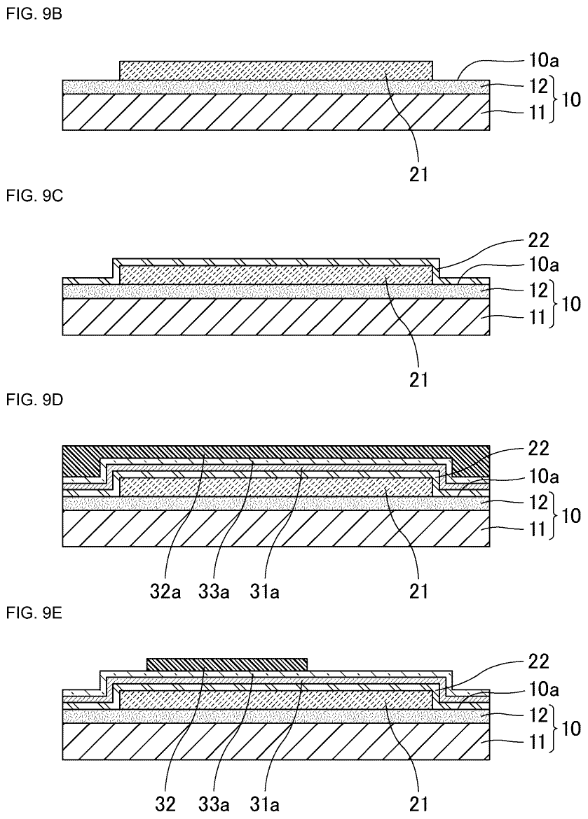

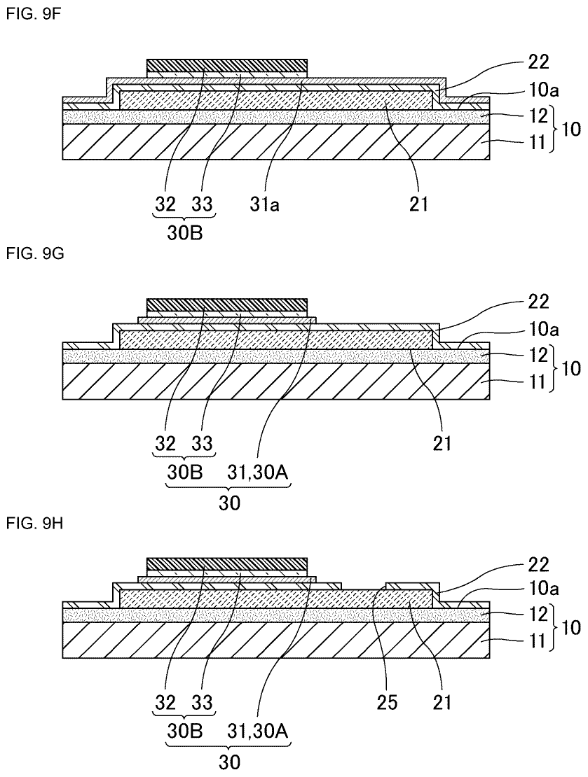

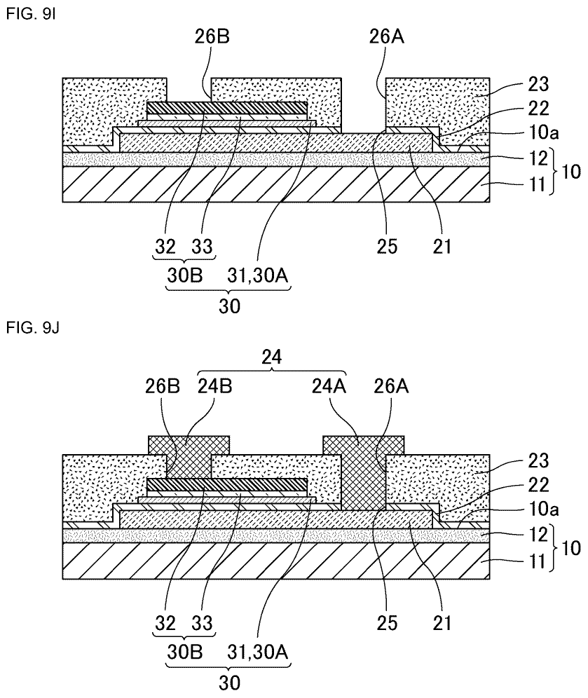

FIG. 9A is a sectional view schematically depicting an example of a step of forming the insulating layer in embodiment 4. FIG. 9B is a sectional view schematically depicting an example of a step of forming the lower electrode in embodiment 4. FIG. 9C is a sectional view schematically depicting an example of a step of forming the dielectric film in embodiment 4. FIG. 9D is a sectional view schematically depicting an example of a step of forming metal films for the upper electrode in embodiment 4. FIG. 9E is a sectional view schematically depicting an example of a first step of processing the metal film for the upper electrode in embodiment 4. FIG. 9F is a sectional view schematically depicting an example of a second step of processing the metal film for the upper electrode in embodiment 4. FIG. 9G is a sectional view schematically depicting an example of a third step of processing the metal film for the upper electrode in embodiment 4. FIG. 9H is a sectional view schematically depicting an example of a step of forming the via in the dielectric film in embodiment 4. FIG. 9I is a sectional view schematically depicting an example of a step of forming the protective layer in embodiment 4. FIG. 9J is a sectional view schematically depicting an example of a step of forming the outer electrodes in embodiment 4.

First, as depicted in FIGS. 9A to 9C, similarly to embodiment 1, the insulating layer 12, the lower electrode 21, and the dielectric film 22 are formed in that order over the semiconductor substrate 11.

Next, as depicted in FIG. 9D, metal films 31a, 33a, and 32a to serve as the lower layer 31, the metal layer 33, and the upper layer 32 of the upper electrode 30 are each formed over the dielectric film 22. As a material of the lower layer 31 (metal film 31a), Cu, Ag, Au, Al, Pt, or an alloy containing at least one of these metals is preferable. As a material of the metal layer 33 (metal film 33a), Ti, Cr, Ta, or an alloy containing at least one of these metals is preferable. As a material of the upper layer 32 (metal film 32a), Cu, Ag, Au, Al, Pt, or an alloy containing at least one of these metals is preferable.

Next, as depicted in FIG. 9E, a resist pattern for the upper layer 32 of the upper electrode 30 is formed by photolithography, and the metal film 32a is processed by etching to form the upper layer 32. At this time, the metal film 33a functions as an etching stopper film. Therefore, a method such as dry etching with high processing accuracy can be used.

Next, as depicted in FIG. 9F, the metal film 33a is processed to form the metal layer 33. Specifically, the metal layer 33 is formed by dry-etching the metal film 33a using the upper layer 32 as a mask.

Next, as depicted in FIG. 9G, a resist pattern for the lower layer 31 of the upper electrode 30 is formed by photolithography, and the lower layer 31 is formed by etching. At this time, it is preferable to use a method such as dry etching with high processing accuracy.

As described above, also in the present embodiment, the upper electrode 30 can be formed without using a method with low processing accuracy, such as lift-off or plating, similarly to embodiment 3.

Although the description has been given of the case in which the metal films 33a and 31a are each patterned to sequentially form the metal layer 33 and the lower layer 31 in order to improve the processing accuracy of the lower layer 31, the metal films 33a and 31a may be collectively patterned to simultaneously form the metal layer 33 and the lower layer 31, depending on the materials of the metal films 33a and 31a.

Thereafter, similarly to embodiment 1, as depicted in FIGS. 9H to 9J, the via 25, the protective layer 23, and the outer electrodes 24 are formed in that order. Then, the obtained structure is thinned to a desired element thickness, followed by dicing into individual pieces.

Through the above process, the capacitor 4 according to the present embodiment is manufactured.

### Embodiment 5

The present embodiment is different from embodiment 2 in that an insulating film is formed between an end portion of a first layer (lower layer) of the upper electrode and an end portion of a second layer (upper layer) of the upper electrode.

FIG. 10 is a sectional view schematically depicting an example of a capacitor according to embodiment 5 of the present disclosure. FIG. 10 corresponds to the sectional view taken along line A-A of the capacitor depicted in FIG. 1.

A capacitor 5 depicted in FIG. 10 further includes an insulating film 27 disposed between an end portion of the upper layer 32 of the upper electrode 30 and an end portion of the lower layer 31 of the upper electrode 30. This provides an effect of relieving stress concentration at the end portion of the upper layer 32 and improving reliability in addition to the effects of embodiment 2.

In the present embodiment, the lower layer 31 corresponds to the lower portion 30A of the upper electrode 30, and the upper layer 32 corresponds to the upper portion 30B of the upper electrode 30. In addition, the end portion of the upper layer 32 is formed in an overhanging shape.

The insulating film 27 may overlap with the end portion of the lower layer 31 of the upper electrode 30 at part of the periphery of the lower layer 31. However, it is preferable that the insulating film 27 overlap with the end portion of the lower layer 31 of the upper electrode 30 in such a manner as to surround the entire periphery of the lower layer 31. That is, it is preferable that the entire peripheral edge portion of the lower layer 31 be covered by the insulating film 27. As a material of the insulating film 27, for example, SiO₂, SiN, Al₂O₃, or the like can be used.

As depicted in FIG. 10, although a width w of the overlapping of the insulating film 27 with the upper layer 32 is not particularly limited, the width w is preferably 1% to 50% of a width W of the upper layer 32, and more preferably 1% to 10% of the width W.

It is to be noted that the percentage of the width w to this width W is calculated on the basis of the widths w and W measured in the same section.

The film thickness of the insulating film 27 is also not particularly limited, but is preferably 0.05 μm to 0.5 μm, and more preferably 0.05 μm to 0.1 μm.

The capacitor 5 according to the present embodiment can be manufactured by a process similar to that of the capacitor 2 according to embodiment 2. However, in the present embodiment, after forming the lower layer 31 of the upper electrode 30 (see FIG. 5D), an insulating film is deposited by CVD, PVD, or the like, and this film is patterned by etching or the like to form the insulating film 27. Thereafter, similarly to embodiment 2, the upper layer 32 of the upper electrode 30, the via 25, the protective layer 23, and the outer electrodes 24 are formed in that order, and then the obtained structure is thinned to a desired element thickness, followed by dicing into individual pieces.

### Other Embodiments

The semiconductor device of the present disclosure is not limited to the above embodiments, and various applications and modifications can be made concerning configurations, manufacturing conditions, and the like of the semiconductor devices such as the capacitors within the scope of the present disclosure.

For example, the semiconductor device of the present disclosure may further include a second upper electrode disposed on the dielectric film separately from the above upper electrode, and the first outer electrode may be connected to the second upper electrode. This makes it possible to form two capacitors with respect to one lower electrode. In this case, it is preferable that this second upper electrode also have a protruding shape in a sectional view.

### REFERENCE SIGNS LIST

1, 2, 3, 4, 5 capacitor (semiconductor device)
10 substrate
10a insulating surface
11 semiconductor substrate
12 insulating layer
21 lower electrode
22 dielectric film
23 protective layer
24 outer electrode
24A first outer electrode
24B second outer electrode
25, 26A, 26B via (opening)
27 insulating film
30 upper electrode
30A lower portion of the upper electrode
30B upper portion of the upper electrode
30a, 31a, 32a, 33a metal film
31 lower layer of the upper electrode
32 upper layer of the upper electrode
33 metal layer of the upper electrode

1. A semiconductor device comprising:
a substrate having an insulating surface;
a first electrode on the insulating surface;
a dielectric film on the lower electrode; and
a second electrode on the dielectric film, wherein
the second electrode has a protruding shape in a sectional view.

2. The semiconductor device according to claim 1, wherein the second electrode has a first layer and a second layer on the lower layer.

3. The semiconductor device according to claim 2, wherein the second layer is only on a main surface of the first layer.

4. The semiconductor device according to claim 2, wherein the second layer covers a main surface and a side surface of the first layer.

5. The semiconductor device according to claim 3, wherein the second electrode further comprises a metal layer between the second layer and the first layer.

6. The semiconductor device according to claim 5, wherein the second layer and the metal layer correspond to the second portion of the second electrode.

7. The semiconductor device according to claim 3, further comprising:
an insulating film between an end portion of the second layer and an end portion of the first layer.

8. The semiconductor device according to claim 7, wherein the insulating film overlaps with the end portion of the first layer of the second electrode so as to surround an entire periphery of the first layer.

9. The semiconductor device according to claim 2, wherein the second layer and the first layer contain a same material.

10. The semiconductor device according to claim 2, wherein the second layer and the first layer contain different materials from each other.

11. The semiconductor device according to claim 1, wherein a thickness of a first portion of the second electrode proximal to the substrate is smaller than a thickness of second portion of the second electrode distal from the substrate.

12. The semiconductor device according to claim 11, wherein the thickness of the first portion is less than 1 μm.

13. The semiconductor device according to claim 12, wherein the thickness of the second portion is 1 μm or more.

14. The semiconductor device according to claim 11, wherein the thickness of the second portion is 1 μm or more.

15. The semiconductor device according to claim 2, wherein a length of each side of the second portion is 50% to 99% of a length of a corresponding side of the first portion.

16. The semiconductor device according to claim 1, wherein the substrate includes a semiconductor substrate and an insulating layer on the semiconductor substrate.

17. The semiconductor device according to claim 1, further comprising:
a protective layer on the dielectric film and the second electrode;
a first outer electrode penetrating the protective layer and the dielectric film and connected to the first electrode; and
a second outer electrode penetrating the protective layer and connected to the second electrode.
